(19) United States
(12) Patent Application Publication
(10) Pub. No.: US 2025/0340979 A1
(43) Pub. Date: Nov. 6, 2025

(54) FILM FORMING METHOD AND FILM FORMING APPARATUS

(71) Applicant: Tokyo Electron Limited, Tokyo (JP)

(72) Inventors: Sena FUJITA, Nirasaki City (JP); Yusuke SUZUKI, Nirasaki City (JP)

(21) Appl. No.: 19/271,888

(22) Filed: Jul. 17, 2025

Related U.S. Application Data
(63) Continuation of application No. PCT/JP2024/000931, filed on Jan. 16, 2024.

(30) Foreign Application Priority Data
Jan. 27, 2023 (JP) 2023-010863

(51) Int. Cl. C23C 16/04; C23C 16/14; C23C 16/30; C23C 16/34; C23C 16/40; C23C 16/455; C23C 16/458; C23C 16/52

(52) U.S. Cl. CPC C23C 16/04; C23C 16/14; C23C 16/308; C23C 16/34; C23C 16/345; C23C 16/405; C23C 16/45542; C23C 16/45544; C23C 16/45553; C23C 16/4583; C23C 16/52

(57) ABSTRACT

A film forming method includes: preparing a substrate including a first film containing boron and a second film made of material different from that of the first film on different regions of a surface of the substrate; and forming a third film selectively on the second film, wherein the forming the third film includes supplying a raw material gas containing halogen and an element X to the surface and supplying a reactant gas reacting with adsorbate of the raw material gas to the surface, thus forming the third film containing the element X, and includes supplying a replacement gas to replace adsorbate of the reactant gas on a surface of the first film during repetition of alternately or simultaneously performing the supplying the raw material gas and the supplying the reactant gas, to prevent adsorption of the raw material gas on the surface of the first film.

### CROSS-REFERENCE TO RELATED APPLICATION

The application is a Bypass Continuation application of PCT International Application No. PCT/JP2024/000931, filed on Jan. 16, 2024 and designating the United States, the international application being based upon and claiming the benefit of priority from Japanese Patent Application No. 2023-010863, filed on Jan. 27, 2023, the entire content of which is incorporated herein by reference.

### TECHNICAL FIELD

The present disclosure relates to a film forming method and a film forming apparatus.

### BACKGROUND

A method of forming a nitride film described in Patent Document 1 includes a step of adsorbing a chlorine gas on surfaces of a first base film and a second base film, and a step of selectively forming a nitride film on one of the first base film and the second base film on which the chlorine gas has been adsorbed.

### PRIOR ART DOCUMENTS

### Patent Documents

Patent Document: Japanese Patent laid-open publication No. 2017-174919

### SUMMARY

According to one embodiment of the present disclosure, a film forming method includes: preparing a substrate including a first film containing boron and a second film made of a material different from that of the first film on different regions of a surface of the substrate; and forming a third film selectively on the second film with respect to the first film. The forming the third film includes supplying a raw material gas containing halogen and an element X other than halogen to the surface of the substrate and supplying a reactant gas that reacts with an adsorbate of the raw material gas to the surface of the substrate, thus forming the third film containing the element X, and includes supplying a replacement gas to replace an adsorbate of the reactant gas on a surface of the first film during repetition of alternately or simultaneously performing the supplying the raw material gas and the supplying the reactant gas, so as to prevent adsorption of the raw material gas on the surface of the first film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a film forming method according to one embodiment of the present disclosure.

FIG. 2 is a flowchart illustrating an example of step S102 illustrated in FIG. 1.

FIG. 3 is a diagram illustrating an exemplary difference between a presence or absence of step S102f illustrated in FIG. 2.

FIG. 4 is a flowchart illustrating a modification of step S102 illustrated in FIG. 1.

FIG. 5 is a flowchart illustrating another modification of step S102 illustrated in FIG. 1.

FIG. 6 is a cross-sectional view illustrating a first example of a film forming method.

FIG. 7 is a cross-sectional view illustrating a second example of a film forming method.

FIG. 8 is a cross-sectional view illustrating a third example of a film forming method.

FIG. 9 is a cross-sectional view illustrating a fourth example of a film forming method.

FIG. 10 is a cross-sectional view illustrating a fifth example of a film forming method.

FIG. 11 is a cross-sectional view illustrating a sixth example of a film forming method.

FIG. 12 is a cross-sectional view illustrating a seventh example of a film forming method.

FIG. 13 is a cross-sectional view illustrating an eighth example of a film forming method.

FIG. 14 is a cross-sectional view illustrating a ninth example of a film forming method.

FIG. 15 is a flowchart illustrating a film forming method according to a modification.

FIG. 16 is a flowchart illustrating an example of step S101B illustrated in FIG. 15.

FIG. 17 is a cross-sectional view illustrating a tenth example of a film forming method.

FIG. 18 is a cross-sectional view illustrating an eleventh example of a film forming method.

FIG. 19 is a cross-sectional view illustrating a film forming apparatus according to one embodiment of the present disclosure.

FIG. 20 is a cross-sectional view illustrating an example of a first processor.

FIG. 21 is an SEM image illustrating a substrate before processing in Example 1.

FIG. 22 is an SEM image illustrating the substrate after processing in Example 1.

FIG. 23 is an SEM image illustrating a substrate after processing in Example 2.

FIG. 24 is an SEM image illustrating a substrate after processing in Example 3.

FIG. 25 is an SEM image illustrating a substrate after processing in Example 4.

FIG. 26 is an SEM image illustrating a substrate after processing in Example 5.

FIG. 27 is an SEM image illustrating a substrate after processing in Example 6.

FIG. 28 is an SEM image illustrating a substrate before processing in Example 7.

FIG. 29 is an SEM image illustrating the substrate after processing in Example 7.

FIG. 30 is an SEM image illustrating a substrate after processing in Example 8.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the accompanying drawings. In addition, in each drawing, the same reference numerals will be given to the same or corresponding components, and descriptions thereof may be omitted.

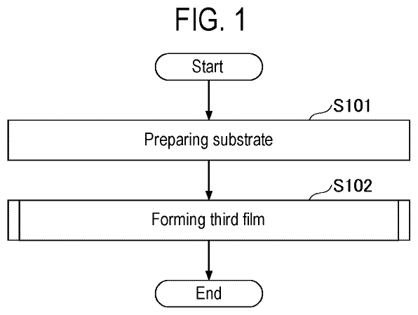

First, a film forming method according to one embodiment of the present disclosure will be described with reference mainly to FIG. 1. The film forming method includes, for example, steps S101 and S102 illustrated in FIG. 1. In addition, the film forming method may include steps other than steps S101 and S102 illustrated in FIG. 1.

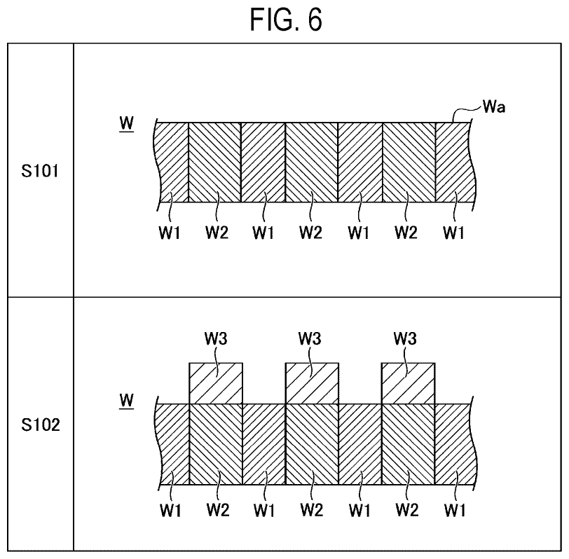

Step S101 includes preparing a substrate W (see, for example, FIG. 6). The substrate W includes a first film W1 containing boron (B) and a second film W2 made of a material different from that of the first film W1, on different regions of a surface Wa. The first film W1 and the second film W2 are formed, for example, on a base substrate (not illustrated). The base substrate is a silicon wafer or compound semiconductor wafer. The compound semiconductor wafer is, for example, a GaAs wafer, a SiC wafer, a GaN wafer, or an InP wafer.

The first film W1 contains boron (B). The content of B in the first film W1 is, for example, 20 atomic % to 100 atomic %, or may be 40 atomic % to 100 atomic %. The first film W1 is, for example, a B film, BN film, BNC film, BO film, BNOC film, SiBN film, SiBCN film, or SiOBN film. Herein, the BN film refers to a film containing boron (B) and nitrogen (N). An atomic ratio of B to N in the BN film is not limited to 1:1. The same applies to films such as a BNC film other than the BN film, meaning that the films contain the respective elements and are not limited to stoichiometric ratios.

The second film W2 is made of a material different from that of the first film W1. The second film W2 substantially does not contain B. Here, the expression “substantially does not contain B” means that the content of B is 0 atomic % to 5 atomic %. The lower the content of B in the second film W2 is, the more desirable it is. The second film W2 may be any one of an insulating film, a conductive film, and a semiconductor film.

The insulating film used as the second film W2 is not particularly limited, but is, for example, a SiO film, a SiN film, a SiOC film, a SiON film, a SiOCN film, a AlO film, a ZrO film, a HfO film, or a TiO film. Here, the SiO film refers to a film containing silicon (Si) and oxygen (O). An atomic ratio of Si to O in the SiO film is usually 1:2, but is not limited to 1:2. The same applies to the SiN film, SiOC film, SiON film, SiOCN film, AlO film, ZrO film, HfO film, and TiO film, meaning that the films contain the respective elements and are not limited to stoichiometric ratios. The insulating film is, for example, an interlayer insulating film. The interlayer insulating film may be a low-dielectric constant (low-k) film.

The semiconductor film used as the second film W2 is not particularly limited, but is, for example, a Si film, a SiGe film, or a GaN film. The semiconductor film may be any one of a single crystal film, a polycrystalline film, and an amorphous film.

The conductive film used as the second film W2 is, for example, a metal film. The metal film is not particularly limited, but is, for example, a Cu film, a Co film, a Ru film, a Mo film, a W film, or a Ti film. The conductive film may also be a metal nitride film. The metal nitride film is not particularly limited, but is, for example, a TiN film or a TaN film. Herein, the TiN film refers to a film containing titanium (Ti) and nitrogen (N). An atomic ratio of Ti to N in the TiN film is usually 1:1, but is not limited to 1:1. The same applies to the TaN film, meaning that the film contains the respective elements and is not limited to stoichiometric ratios.

Step S102 includes selectively forming a third film W3 on the second film W2 with respect to the first film W1 (see, e.g., FIG. 6). Step S102 includes alternately or simultaneously supplying a raw material gas that contains halogen and an element X other than halogen and a reactant gas that reacts with an adsorbate of the raw material gas to a substrate surface Wa, thereby forming the third film W3 containing the element X.

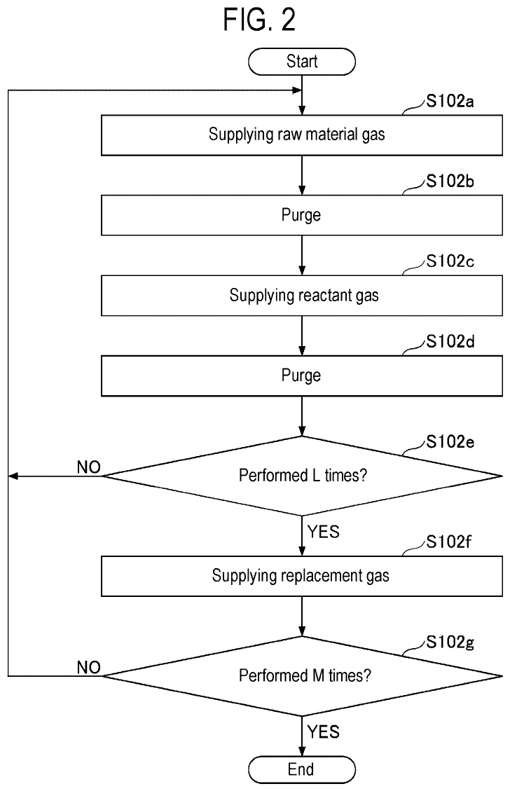

Step S102 includes, for example, steps S102a to S102g, as illustrated in FIG. 2. In addition, step S102 only needs to include at least steps S102a, S102c, S102f and S102g, and may not include steps S102b, S102d and S102e. The following describes steps S102a to S102g.

Step S102a includes supplying a raw material gas to the substrate surface Wa. The raw material gas contains halogen and an element X other than halogen. The halogen is fluorine, chlorine, bromine, or iodine. The element X is not particularly limited, but may be a metal element, and more particularly a transition metal element. The element X is, for example, Ti, W, V, Al, Mo, Sn, Hf, Ta, Nb, Zr, In, Ga or Sb. A specific example of the raw material gas may include a TiCl₄ gas, a WCl₆ gas, a WF₆ gas, a VCl₄ gas, an AlCl₃ gas, a MoCl₅ gas, a SnCl₄ gas, HfCl₄ gas, TaCl₅ gas, a NbCl₅ gas, a ZrCl₄ gas, an InCl₃ gas, a GaCl₃ gas or a SbCl₃ gas. The element X may also be a semiconductor element, specifically Si or Ge. The raw material gas may be a halogenated silicon gas or halogenated germanium gas. A specific example of the halogenated silicon gas may include a SiCl₄ gas, a SiHCl₃ gas, a SiH₂Cl₂ gas, a SiH₃Cl gas, a Si₂Cl₆ gas, a Si₂HCl₅ gas, a Si₂Cl₃CH₃ gas, a SiCl₃CCl₃ gas, a SiCl₃CH₃ gas, or a SiH₂I₂ gas. A specific example of the halogenated germanium gas may include a GeCl₄ gas. The raw material gas may be supplied together with a dilution gas. The dilution gas is, for example, an Ar gas or a N₂ gas.

Step S102b includes supplying a purge gas to the substrate surface Wa. The purge gas purges any excess raw material gas that has not been adsorbed on the substrate surface Wa in step S102a. The purge gas is, for example, a noble gas such as an Ar gas, or a N₂ gas.

Step S102c includes supplying a reactant gas to the substrate surface Wa. The reactant gas reacts with the element X contained in an adsorbate of the raw material gas, thereby forming the third film W3 containing the element X. The reactant gas may be an oxygen-containing gas, a nitrogen-containing gas, or a hydrogen-containing gas. The oxygen-containing gas contains oxygen and forms an oxide film of the element X. The oxygen-containing gas is, for example, an O₂ gas, an O₃ gas, a CO₂ gas, a N₂O gas, a NO gas, or a H₂O gas. The nitrogen-containing gas contains nitrogen and forms a nitride film of the element X. The nitrogen-containing gas is, for example a NH₃ gas or a N₂H₄ gas. The hydrogen-containing gas contains hydrogen and forms a film containing the element X as a main component (e.g., a metal film or a semiconductor film). The hydrogen-containing gas is, for example, a H₂ gas or a H₂S gas. The reactant gas may be supplied together with a dilution gas. The dilution gas is, for example, an Ar gas or a N₂ gas.

Step S102c may include forming the reactant gas into a plasma, and may include supplying the reactant gas formed into the plasma to the substrate surface Wa. By forming the reactant gas into the plasma, it is possible to promote formation of the third film W3.

In addition, the reactant gas may be supplied not only in step S102c but also in all steps S102a to S102d. However, the forming the reactant gas into the plasma is performed only in step S102c. This is because by being formed into the plasma, the reactant gas becomes more reactive with the adsorbate of the raw material gas on the substrate surface Wa.

Step S102c may include supplying an O₃ gas as the reactant gas to the substrate surface Wa without forming the O₃ gas into a plasma.

Step S102d includes supplying a purge gas to the substrate surface Wa. The purge gas purges any excess reactant gas that did not react with the substrate surface Wa in step S102c. The purge gas is, for example, a noble gas such as Ar gas, or a N₂ gas.

Step S102e includes checking whether steps S102a to S102d have been performed L times (L is an integer of 1 or more). In this case, L may be an integer of 2 or more, and steps S102a to S102d may be performed repeatedly. A film thickness of the third film W3 may be increased.

If the number of executions of steps S102a to S102d is less than L (step S102e, “NO”), since the film thickness of the third film W3 is less than a target value, steps S102a to S102d are performed again. In this case, L may be 200 or more, and more specifically 300 or more. Further, L may be 1000 or less.

On the other hand, if the number of executions of steps S102a to S102d has reached L (step S102e, “YES”), since the film thickness of the third film W3 has reached the target value, step S102f described below is performed.

In addition, a method of forming the third film W3 illustrated in FIG. 2 is an atomic layer deposition (ALD) method, but may also be a chemical vapor deposition (CVD) method. In the ALD method, the supplying the raw material gas (step S102a) and the supplying the reactant gas (step S102c) are performed alternately. On the other hand, in the CVD method, the supplying the raw material gas and the supplying of the reactant gas are performed simultaneously.

To inhibit the formation of the third film W3 on the surface of the first film W1, it is important that the adsorption of the raw material gas on the first film W1 is weak, and as a result, the adsorbate of the raw material gas desorbs from the surface of the first film W1 without proceeding a film forming reaction (formation of the third film W3). Alternatively, it is important that the raw material gas does not adsorb on the surface of the first film W1, or that dissociation of the raw material gas on the surface of the first film W1 is unlikely to occur. The film forming reaction tends to proceed in a case where dissociation of the raw material gas occurs.

It is considered that, since the first film W1 contains boron, halide adsorption does not occur, or occurs weakly on the first film W1, or halide dissociation is unlikely to occur. As a result, the formation of the third film W3 on the surface of the first film W1 is inhibited.

On the other hand, it is considered that, since the second film W2 substantially does not contain boron, a halide is strongly adsorbed on the second film W2, or halide dissociation is likely to occur on the second film W2. As a result, it is considered that the formation of the third film W3 proceeds on the surface of the second film W2.

Further, a halide such as TiCl₄ is less likely to decompose due to heat of the substrate W, compared to an organometallic complex such as Ti[N(CH₃)₂]₄. In a case where the raw material gas decomposes after being adsorbed on the first film W1, the formation of the third film W3 may proceed. Therefore, to inhibit the formation of the third film W3 on the surface of the first film W1, a gas containing halogen is suitable for the raw material gas for the third film W3.

Furthermore, in a plasma CVD method in which both the halide and the reactant gas are formed into a plasma, active species such as ions or radicals are generated from the dissociation of the halide. It is considered that since the active species generated from the halide are highly reactive, the film forming reaction is likely to proceed not only on the surface of the second film W2 but also on the surface of the first film W1. Therefore, it is desirable not to form the raw material gas into the plasma, and it is important to use a thermal ALD method, a plasma ALD method, or a thermal CVD method.

In the above steps S102a to S102d, the temperature of the substrate W may be controlled to 100 degrees C. or higher, so as to promote desorption of the raw material gas from the surface of the first film W1. In a case where the temperature of the substrate W is less than 100 degrees C., the raw material gas may not sufficiently desorb from the surface of the first film W1 and be physically adsorbed on the surface, resulting in the formation of the third film W3 even on the surface of the first film W1. The temperature of the substrate W may be 300 degrees C. or higher. The temperature of the substrate W may be 800 degrees C. or lower.

Step S102f includes supplying a replacement gas to replace an adsorbate of the reactant gas on the surface of the first film W1, so as to prevent the adsorption of the raw material gas on the surface of the first film W1, during repetition of alternately or simultaneously performing the supplying the raw material gas (step S102a) and the supplying the reactant gas (step S102c).

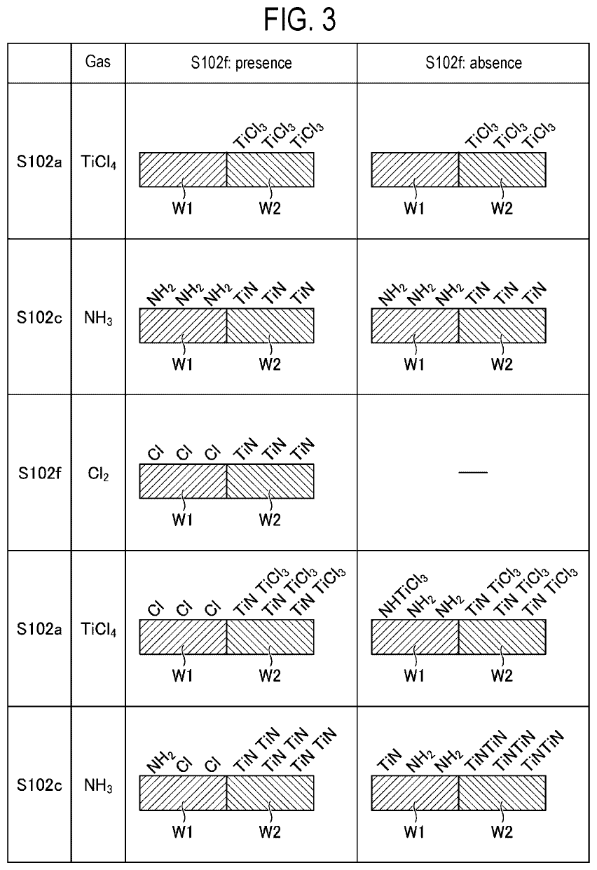

Referring to FIG. 3, an example of difference due to presence or absence of the supplying the replacement gas (step S102f) will be described. In FIG. 3, the first film W1 is a BN film, the second film is a SiO film, the raw material gas is a TiCl₄ gas, the reactant gas is NH₃ gas, the replacement gas is a Cl₂ gas, and the third film W3 is a TiN film. The left column of FIG. 3 illustrates a film formation example when step S102f is performed, and the right column of FIG. 3 illustrates a film formation example when step S102f is not performed.

As illustrated in the right column of FIG. 3, in a case where the supplying the replacement gas (step S102f) is not performed, repetition of alternately or simultaneously performing the supplying the raw material gas (step S102a) and the supplying the reactant gas (step S102c) may result in weakening the effect of inhibiting the formation of the third film W3 on the surface of the first film W1.

Specifically, there are cases where the adsorption of the raw material gas and the film forming reaction for the third film W3 proceed starting from the adsorbate of the reactant gas on the surface of the first film W1. Such a phenomenon is remarkable when the reactant gas is a hydrogen-containing gas. It is considered that hydrogen serves as a starting point for the adsorption of the raw material gas and the film forming reaction for the third film W3 (including dissociation of the raw material gas). The greater the number of execution of steps S102a and S102c is, the weaker the effect of inhibiting the formation of the third film W3 on the surface of the first film W1 becomes.

As illustrated in the left column of FIG. 3, by performing step S102f during repetition of alternately or simultaneously performing steps S102a and S102c, the adsorbate of the reactant gas (e.g., NH₂) on the surface of the first film W1 may be replaced with an adsorbate of the replacement gas (e.g. Cl). Thus, the adsorption of the raw material gas (e.g., adsorption of TiCl₃) and the film forming reaction for the third film W3 (e.g., TiN film) may be prevented on the surface of the first film W1.

The replacement gas may be, for example, a halogen-containing gas, an oxygen-containing gas, or a nitrogen-containing gas. The replacement gas may be a gas that does not contain hydrogen, but may contain hydrogen in a case where the replacement gas is a halogen-containing gas. The halogen-containing gas is a gas that contains halogen, and is, for example, a Cl₂ gas, a Br₂ gas, a F₂ gas, a ClF₃ gas, a NF₃ gas, a HBr gas, a HF gas, a HCl gas, or a HI gas. The oxygen-containing gas is a gas that contains oxygen, and is, for example, an O₂ gas, an O₃ gas, a CO₂ gas, a N₂O gas, or a NO gas. The nitrogen-containing gas is a gas that contains nitrogen, and is, for example, a N₂ gas.

The halogen-containing gas used as the replacement gas constitutes components that are less likely to remain in the third film W3, and specifically constitutes only halogen, or halogen and nitrogen, or halogen and hydrogen. It is considered that, in a case where the replacement gas contains both halogen and hydrogen, halogen tends to be adsorbed to the surface of the first film W1 more strongly than hydrogen, and therefore, replacement of the adsorbate proceeds even in a case where the replacement gas contains hydrogen. In a case where the halogen-containing gas is used as the replacement gas, components of the halogen-containing gas are unlikely to remain in the third film W3, and the composition of the third film W3 is mainly determined by combination of the raw material gas and the reactant gas.

In a case where the replacement gas is the oxygen-containing gas, there are cases where oxygen remains in the third film W3. In a case where the reactant gas is the oxygen-containing gas, the replacement gas may be either the oxygen-containing gas or the halogen-containing gas. On the other hand, in a case where the replacement gas is the nitrogen-containing gas, there are cases where nitrogen remains in the third film W3. In a case where the reactant gas is the nitrogen-containing gas, the replacement gas may be either the nitrogen-containing gas or the halogen-containing gas.

Step S102g includes checking whether a first cycle, in which steps S102a to S102d are performed L times (L is an integer of 1 or more), has been performed M times (M is an integer of 2 or more). If the number of executions of the first cycle is less than M (step S102g, “NO”), since the film thickness of the third film W3 is less than a target value, the first cycle is performed again. In this case, M may be 200 or more, and more specifically 300 or more. Further, M may be 1000 or less.

On the other hand, if the number of executions of the first cycle reaches M (step S102g, “YES”), since the film thickness of the third film W3 has reached the target value, the current processing is terminated.

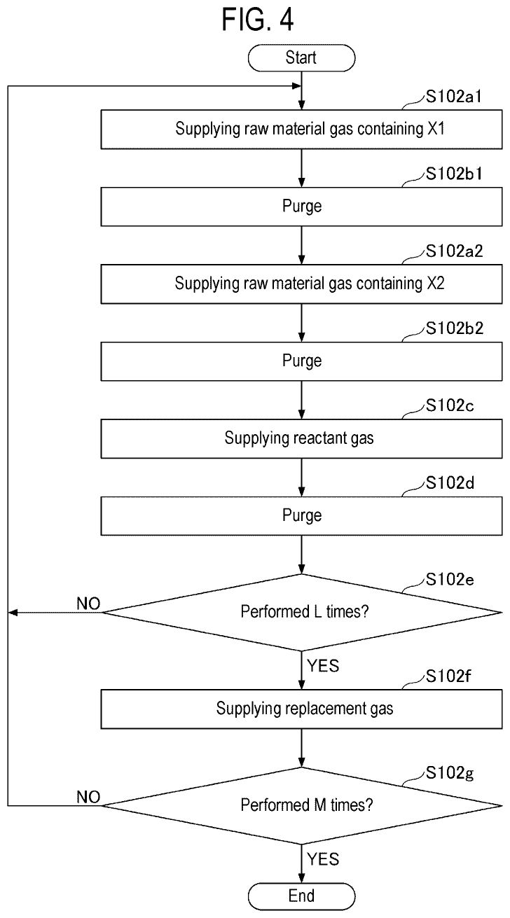

Next, a modification of step S102 will be described with reference to FIG. 4. The following mainly describes differences. As illustrated in FIG. 4, step S102 includes performing a process, one or more times, that includes sequentially performing: supplying a raw material gas containing an element X1 as the element X (step S102a1), supplying a raw material gas containing an element X2, which is different from the element X1, as the element X (step S102a2), and supplying a reactant gas that reacts with an adsorbate of the raw material gas (step S102c).

In addition, a purge gas may be supplied (step S102b1) between step S102al and step S102a2. Further, a purge gas may be supplied (step S102b2) between step S102a2 and step S102c.

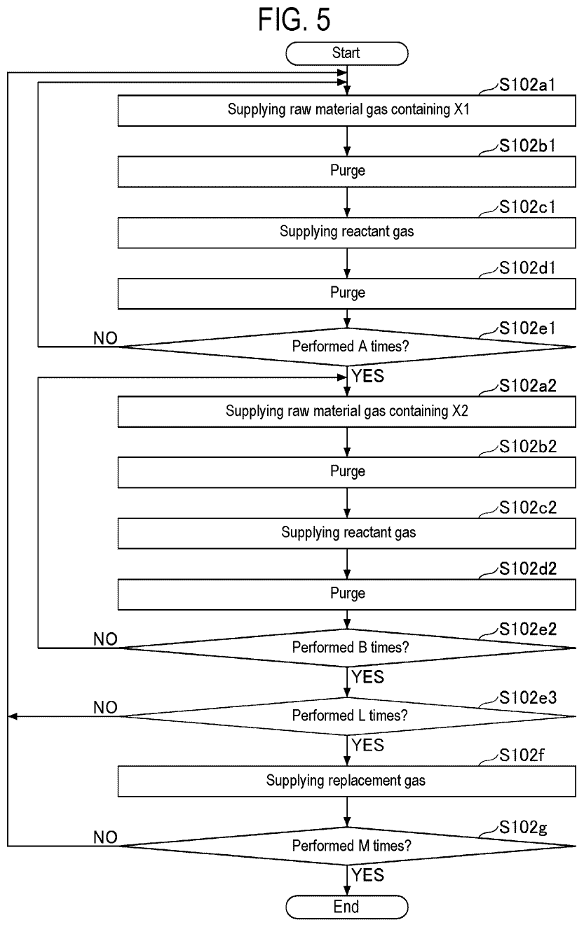

Next, another modification of step S102 will be described with reference to FIG. 5. The following mainly describes differences. As illustrated in FIG. 5, step S102 includes performing a process, one or more times, that includes sequentially performing: supplying a raw material gas containing an element X1 as the element X (step S102al), and supplying a reactant gas that reacts with an adsorbate of the raw material gas (step S102cl). Further, step S102 includes performing a process, one or more times, that includes sequentially performing: supplying a raw material gas containing an element X2, which is different from the element X1, as the element X (step S102a2), and supplying a reactant gas that reacts with an adsorbate of the raw material gas (step S102c2).

In step S102e1 of FIG. 5, A may be an integer of 1 or more, and may also be an integer of 2 or more. In a case where A is an integer of 2 or more, steps S102a1, S102b1, S102cl, and S102d1 are repeated multiple times. Further, in step S102e2 of FIG. 5, B may be an integer of 1 or more, and may also be an integer of 2 or more. In a case where B is an integer of 2 or more, steps S102a2, S102b2, S102c2, and S102d2 are repeated multiple times.

In addition, a purge gas may be supplied (step S102b1) between steps S102al and S102c1. Further, a purge gas may be supplied (step S102d1) immediately after step S102cl. Further, a purge gas may be supplied (step S102b2) between step S102a2 and step S102c2. Further, a purge gas may be supplied (step S102d2) immediately after step S102c2.

In FIGS. 4 and 5, one of the element X1 and the element X2 is a metal element (specifically, a transition metal element), and the other is a semiconductor element. In addition, combination of the elements X1 and X2 in FIGS. 4 and 5 is not particularly limited. The combination of the elements X1 and X2 may be combination of metal elements or combination of semiconductor elements. In any case, the third film W3 containing both the elements X1 and X2 is obtained. The element X may further include an element X3 that is different from the elements X1 and X2, or may include three or more elements different from one another. The raw material gas containing the element X3 may also be supplied.

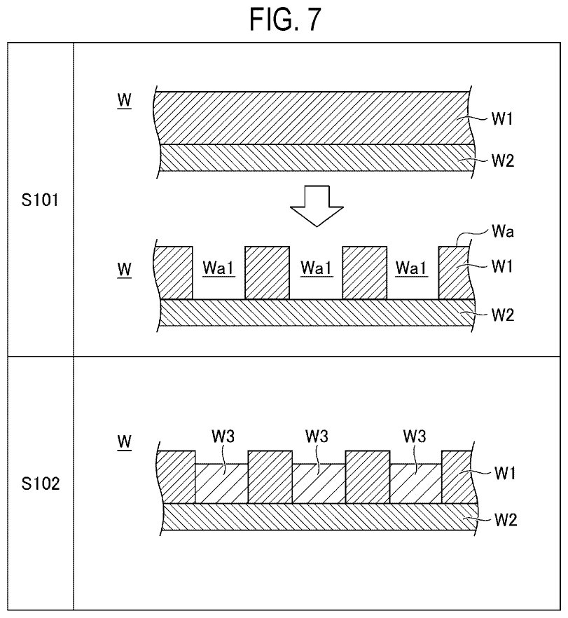

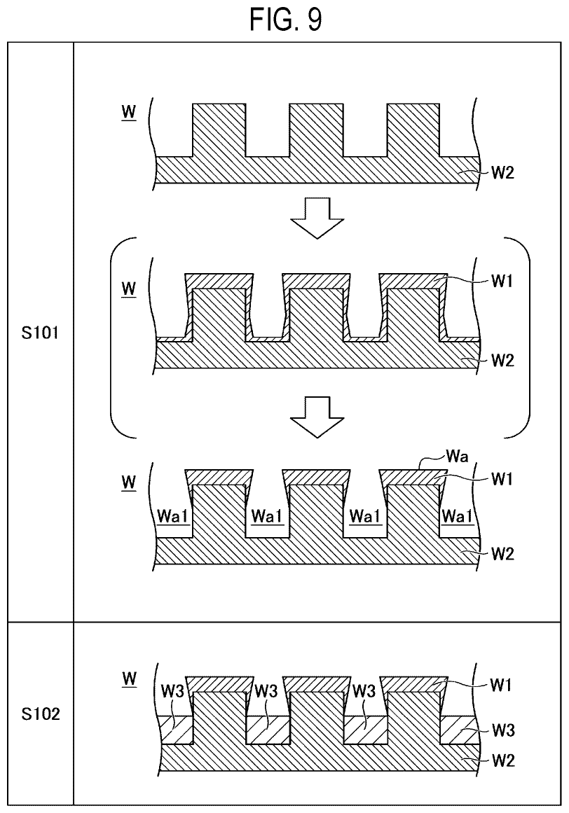

Next, a case will be described, in which the substrate W prepared in step S101 has a recess Wa1 on the surface Wa, and the second film W2 is exposed only in the inside of the recess Wa1, with reference to FIGS. 7 to 9. The second film W2 is exposed at least on the bottom surface of the recess Wa1, as illustrated in FIGS. 7 to 9. In this case, by performing the processes following step S102, the inside of the recess Wa1 may be filled with the third film W3. In addition, the recess Wa1 is partially filled with the third film W3 in FIGS. 7 to 9, but the entire recess Wa1 may be filled. In the latter case, in FIG. 9, the first film W1 may remain only on a top surface of a protrusion of the second film W2 by etching.

In step S101 of FIG. 7, first, the first film W1 is formed over the entire surface of the second film W2, and then a portion of the surface of the first film W1 is etched. As a result, the recess Wa1 is formed through a portion of the first film W1, and the second film W2 is exposed only on the bottom surface of the recess Wa1. Thereafter, by performing the processes following step S102, the third film W3 grows only on the bottom surface of the recess Wa1.

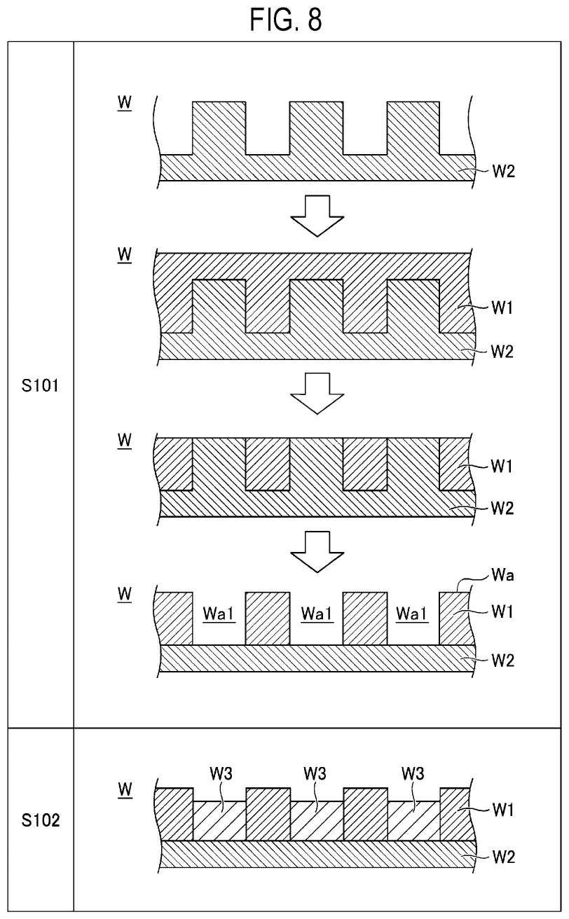

In step S101 of FIG. 8, first, a portion of the surface of the second film W2 is etched to form a recess in the surface of the second film W2. Next, the first film W1 is formed to fill the recess. Next, the first film W1 is processed by chemical mechanical polishing (CMP) or etching until the second film W2 is exposed. Finally, the second film W2 is selectively etched with respect to the first film W1. As a result, the recess Wa1 is formed through a portion of the first film W1, and the second film W2 is exposed only on the bottom surface of the recess Wa1. Thereafter, by performing the processes following step S102, the third film W3 grows only on the bottom surface of the recess Wa1.

In step S101 of FIG. 9, first, a portion of the surface of the second film W2 is etched to form a recess on the surface of the second film W2. Next, the first film W1 is selectively formed on the outside of the recess (i.e., on the top surface of the protrusion) with respect to the inside of the recess. As a result, the second film W2 is exposed on the bottom surface and a lower portion of the side surface of the recess Wa1. In addition, in a case where the first film W1 is also deposited on the bottom surface of the recess Wa1 during step S101, the first film W1 deposited on the bottom surface is removed by, e.g., etching. Thereafter, by performing the processes following step S102, the third film W3 grows on the bottom surface and the lower portion of the side surface of the recess Wa1.

Next, a case will be described, in which the substrate W prepared in step S101 has the recess Wa1 on the surface Wa, and the first film W1 is only exposed inside the recess Wa1, with reference to FIGS. 10 to 12. The first film W1 is exposed at least on the bottom surface of the recess Wa1, as illustrated in FIGS. 10 to 12. In this case, by performing the processes following step S102, the third film W3 may be formed on the surface other than the bottom surface of the recess Wa1.

In step S101 of FIG. 10, first, the second film W2 is formed over the entire surface of the first film W1, and then a portion of the surface of the second film W2 is etched. As a result, the recess Wa1 is formed through a portion of the second film W2, and the first film W1 is exposed only on the bottom surface of the recess Wa1. Thereafter, by performing the processes following step S102, the third film W3 grows on the side surface of the recess Wa1 and on the outside of the recess Wa1 (i.e., on top surface of the protrusion).

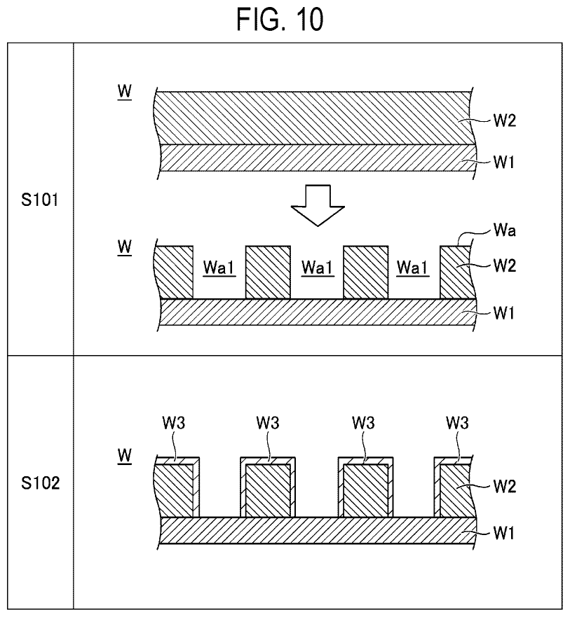

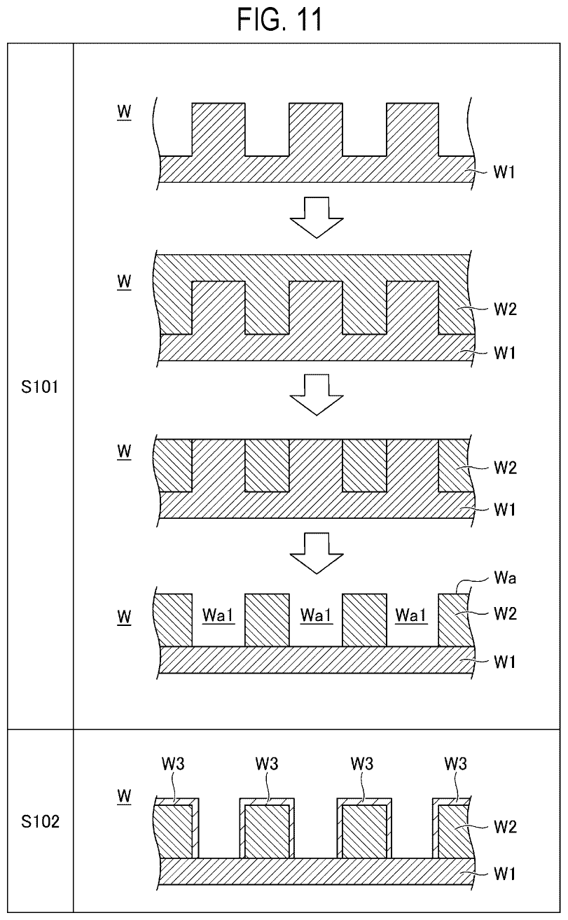

In step S101 of FIG. 11, first, a portion of the surface of the first film W1 is etched to form a recess on the surface of the first film W1. Next, the second film W2 is formed to fill the recess. Next, the second film W2 is processed by CMP or etching until the first film W1 is exposed. Finally, the first film W1 is selectively etched with respect to the second film W2. As a result, the recess Wa1 is formed through a portion of the second film W2, and the first film W1 is exposed only on the bottom surface of the recess Wa1. Thereafter, by performing the processes following step S102, the third film W3 grows on the side surface of the recess Wa1 and on the outside of the recess Wa1 (i.e., on the top surface of the protrusion).

In step S101 of FIG. 12, first, a portion of the surface of the first film W1 is etched to form a recess on the surface of the first film W1. Next, the second film W2 is selectively formed on the outside of the recess (i.e., on the top surface of the protrusion) with respect to the inside of the recess. As a result, the first film W1 is exposed on the bottom surface and a lower portion of the side surface of the recess Wa1. In addition, in a case where the second film W2 is also deposited on the bottom surface of the recess Wa1 during step S101, the second film W2 deposited on the bottom surface is removed by, e.g., etching. Thereafter, by performing the processes following step S102, the third film W3 grows on the outside of the recess (i.e., on the top surface of the protrusion) and on an upper portion of the side surface of the recess Wa1. The third film W3 may enclose an internal void (air gap) of the recess Wa1, as illustrated in FIG. 12.

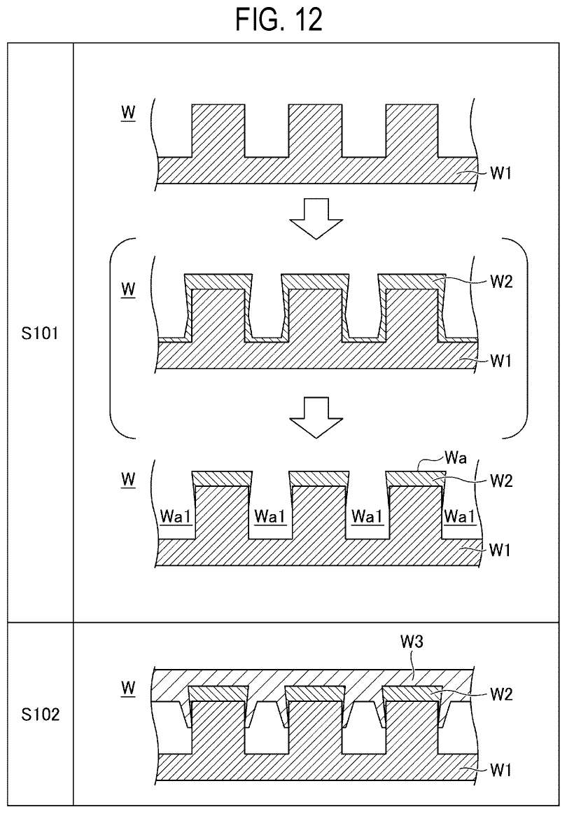

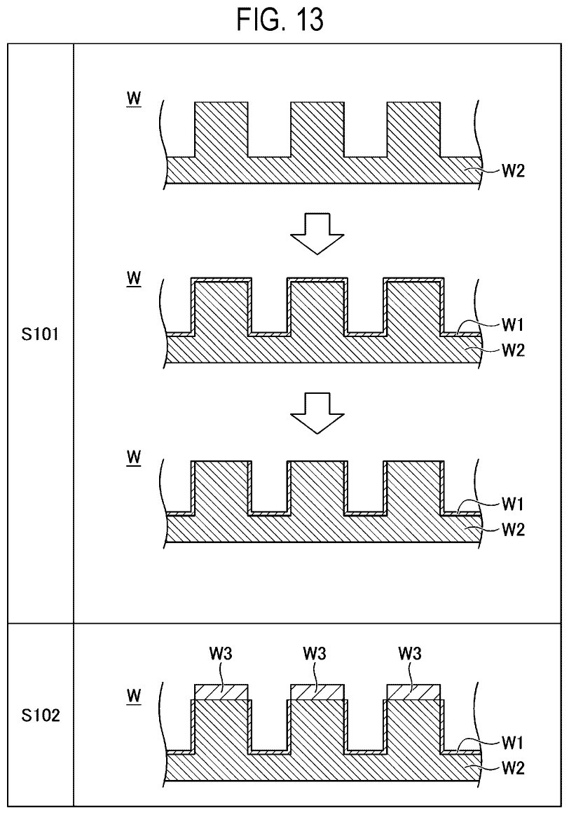

Next, a modification of step S101 will be described with reference to FIG. 13. In step S101 of FIG. 13, first, the second film W2 having an uneven pattern is prepared. Next, the first film W1 is formed along the uneven pattern of the second film W2 over the entire second film W2 by using an ALD method or a CVD method. Next, the top surface of the protrusion of the second film W2 is exposed by CMP or etching. At this time, the first film W1 remains on the side surface and bottom surface of the recess of the second film W2. Thereafter, by performing the processes following step S102, the third film W3 may be formed on the top surface of the protrusion.

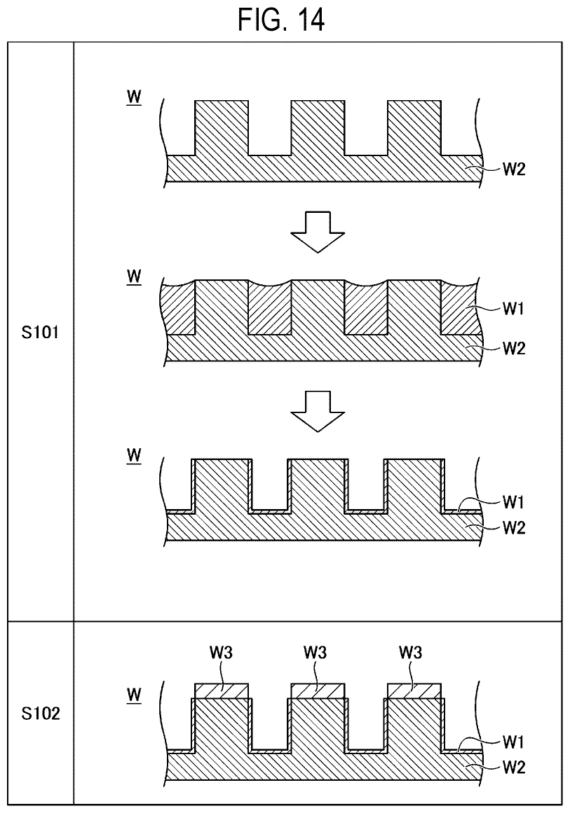

Next, another modification of step S101 will be described with reference to FIG. 14. In step S101 of FIG. 14, first, the second film W2 having an uneven pattern is prepared. Next, the first film W1 is formed to fill a recess of the second film W2. The first film W1 is in a liquid state. The liquid is, for example, a B-containing molecule with an organic ligand such as tris(dimethylamino)borane (TDMAB: C₆H₁₈BN₃), polymerized by using, e.g., a N₂ plasma. Next, the liquid filling the recess of the second film W2 is decomposed by using, e.g., an O₂ plasma, so that the first film W1 remains on the side surface and bottom surface of the recess of the second film W2. The top surface of the protrusion of the second film W2 remains exposed. Although not illustrated, the liquid filling the recess of the second film W2 may be modified by using, e.g., a H₂ plasma to form the first film W1 filling the recess of the second film W2. Thereafter, by performing the processes following step S102, the third film W3 may be formed on the top surface of the protrusion.

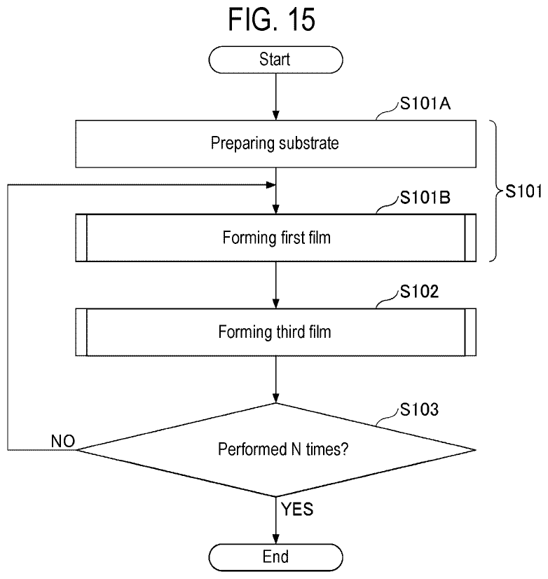

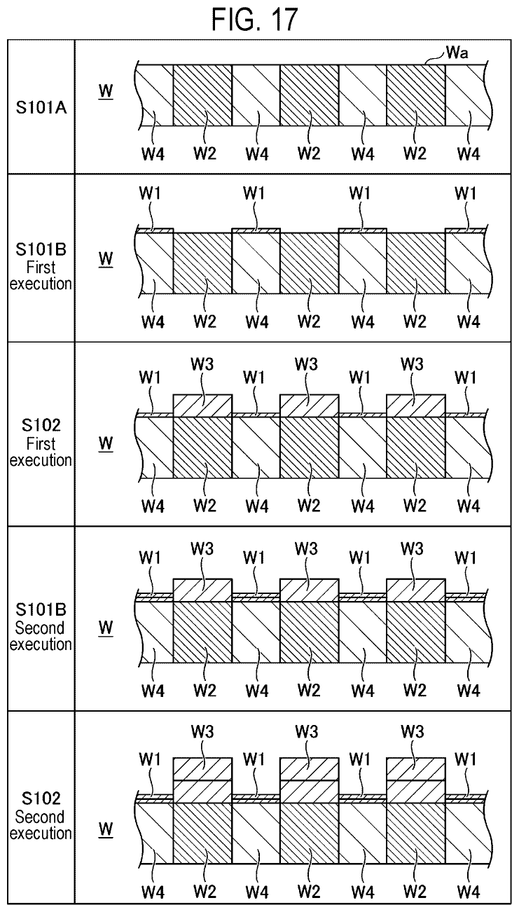

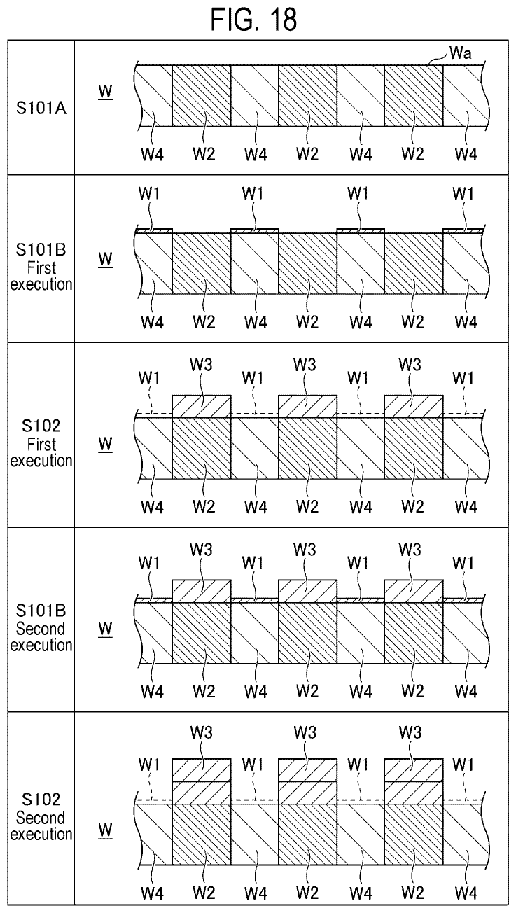

Next, a film forming method according to a modification will be described with reference to FIGS. 15 to 18. The following mainly describes differences. Step S101 may include, for example, preparing the substrate W having the second film W2 and a fourth film W4 made of a material different from that of the second film W2 on different regions of the surface Wa (step S101A), and selectively forming the first film W1 on the fourth film W4 with respect to the second film W2 (step S101B), as illustrated in FIGS. 17 and 18.

The fourth film W4 may be any film that allows the first film W1 to be selectively formed on the fourth film W4 with respect to the second film W2, and may be any one of an insulating film, a conductive film, and a semiconductor film. For example, it is sufficient as long as an incubation time of the first film W1 with respect to the second film W2 is longer than an incubation time of the first film W1 with respect to the fourth film W4. The first film W1 may be selectively formed by using such difference in incubation time. The incubation time refers to time difference from the start of film formation (e.g., the start of the supply of the raw material gas or the reactant gas) to an actual start of film formation.

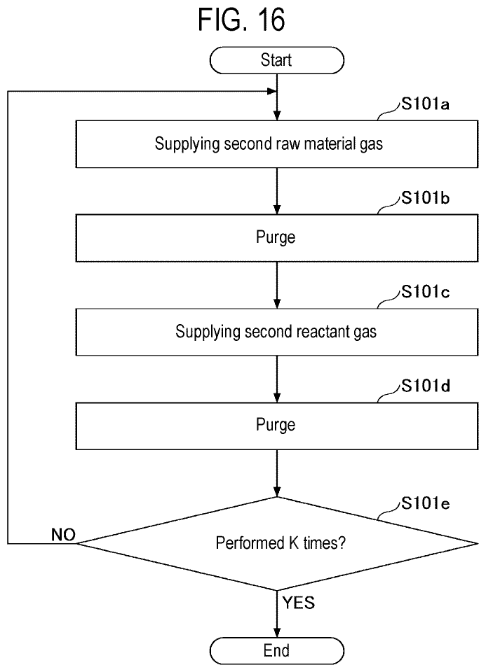

Step S101B includes, for example, steps S101a to S101e, as illustrated in FIG. 16. In addition, step S101B only needs to include steps S101a and S101c, and may not include steps S101b, S101d, and S101e. The following describes steps S101a to S101e.

Step S101a includes supplying a second raw material gas to the substrate surface Wa. The second raw material gas contains boron. For example, the second raw material gas contains tris(dimethylamino)borane (TDMAB: C₆H₁₈BN₃). The second raw material gas may be supplied together with a dilution gas. The dilution gas is, for example, an Ar gas or a N₂ gas.

In addition, the second raw material gas is not limited to one containing TDMAB, and may be, for example, one containing diborane (B₂H₆), boron trichloride (BCl₃), boron trifluoride (BF₃), trisethylmethylaminoborane (C₉H₂₄BN₃), trimethylborane (C₃H₉B), triethylborane (C₆H₁₅B), or cyclotriborazane (B₃N₃H₆).

Step S101b includes supplying a purge gas to the substrate surface Wa. The purge gas purges any excess second raw material gas that has not been adsorbed on the substrate surface Wa in step S101a. The purge gas is, for example, a noble gas such as an Ar gas, or a N₂ gas.

Step S101c includes supplying a second reactant gas to the substrate surface Wa. The second reactant gas reacts with an adsorbate of the second raw material gas on the substrate surface Wa, thereby forming the first film W1. The second reactant gas includes, for example, at least one selected from the group of a nitrogen-containing gas, an oxygen-containing gas, and a reducing gas. The nitrogen-containing gas nitrides the second raw material gas, thereby forming a boron nitride film. The nitrogen-containing gas includes, for example, NH₃, N₂, N₂H₄ or N₂H₂. The oxygen-containing gas oxidizes the second raw material gas, thereby forming a boron oxide film. The oxygen-containing gas includes, for example, O₂, O₃, H₂O, NO, or N₂O. The reducing gas reduces the second raw material gas, forming a boron film. The reducing gas includes, for example, a H₂ gas, a SiH₄ gas or a H₂S gas. The second reactant gas may be supplied together with a dilution gas such as an Ar gas.

Step S101c may include forming the second reactant gas into a plasma, and may include supplying the second reactant gas formed into the plasma to the substrate surface Wa. By forming the second reactant gas into the plasma, it is possible to promote the formation of the first film W1.

In addition, the second reactant gas may be supplied not only in step S101c but also in all steps S101a to S101d. However, the forming the second reactant gas into the plasma is performed only in step S101c. This is because by being formed into the plasma, the second reactant gas promotes the reaction with the adsorbate of the second raw material gas on the substrate surface Wa.

Step S101d includes supplying a purge gas to the substrate surface Wa. The purge gas purges any excess second reactant gas that did not react with the substrate surface Wa in step S101c. The purge gas is, for example, a noble gas such as an Ar gas, or a N₂ gas.

Step S101e includes checking whether steps S101a to S101d have been performed K times (K is an integer of 1 or more). In this case, K may be an integer of 2 or more, and steps S101a to S101d may be performed repeatedly. A film thickness of the first film W1 may be increased.

If the number of executions of steps S101a to S101d is less than K (step S101e, “NO”), since the film thickness of the first film W1 is less than a target value, steps S101a to S101d are performed again. The first film W1 serves to inhibit the formation of the third film W3 in step S102, and may be formed to be thick so as not to expose the fourth film W4. The fourth film W4 is different from the first film W1 in that the fourth film W4 substantially does not contain boron.

It is considered that the first film W1 is formed as nuclei grow on the surface of the fourth film W4 and neighboring nuclei come into contact with one another. It is considered that there is an exposed portion of the fourth film W4 in a dispersed manner until the nuclei reach a sufficient size. Therefore, the film thickness of the first film W1 may be 10 Å or more. It is considered that, if the film thickness of the first film W1 is less than 10 Å, there is an exposed portion of the fourth film W4, and the effect of inhibiting the formation of the third film W3 is weakened.

On the other hand, if the number of executions of steps S101a to S101d has reached K (step S101e, “YES”), since the film thickness of the first film W1 has reached the target value, the current step S101 is terminated.

In addition, a method of forming the first film W1 illustrated in FIG. 16 is an ALD method, but may also be a CVD method. In the ALD method, the supplying the second raw material gas and the supplying the second reactant gas are alternately performed. On the other hand, in the CVD method, the supplying the second raw material gas and the supplying the second reactant gas are performed simultaneously.

In addition, the first film W1 may be a molecular film in which molecules are chemically or physically adsorbed. The molecules are supplied to the substrate surface in a gaseous state. The gas has, in the molecules, functional groups that tend to be adsorbed selectively to a desired region on the substrate surface, and also contains boron (B) in the molecules. The first film W1 may be obtained by decomposition of the adsorbed molecules by heat from the substrate W.

Step S103 (see FIG. 15) includes checking whether a series of processes has been performed N times (N is an integer of 1 or more). The series of processes includes formation of the first film W1 (step S101B) and formation of the third film W3 (step S102). This series of processes is also referred to as a second cycle. If the number of executions of the second cycle is less than N (step S103, “NO”), since the film thickness of the third film W3 is insufficient, the second cycle is performed again. On the other hand, if the number of executions of the second cycle reaches N (step S103, “YES”), the current processing is terminated. In this case, N may be an integer of 2 or more. If N is an integer of 2 or more, the film thickness of the third film W3 may be increased while supplementing the first film W1.

Next, a film forming method in a case where N is an integer of 2 or more will be described with reference to FIGS. 17 and 18. If N is an integer of 2 or more, the second cycle is repeatedly performed multiple times.

Step S101B in and after the second execution includes selectively forming the first film W1 again on the first film W1 with respect to the third film W3 (see FIG. 17). In addition, at step S102 in the first execution (formation of the third film W3), the first film W1 may become thinner and the first film W1 may disappear (see FIG. 18). In a case where the first film W1 disappears, step S101B in and after the second execution includes selectively forming the first film W1 again on the fourth film W4 instead of the first film W1 (see FIG. 18).

Step S102 in and after the second execution includes selectively forming the third film W3 again on the third film W3 with respect to the first film W1.

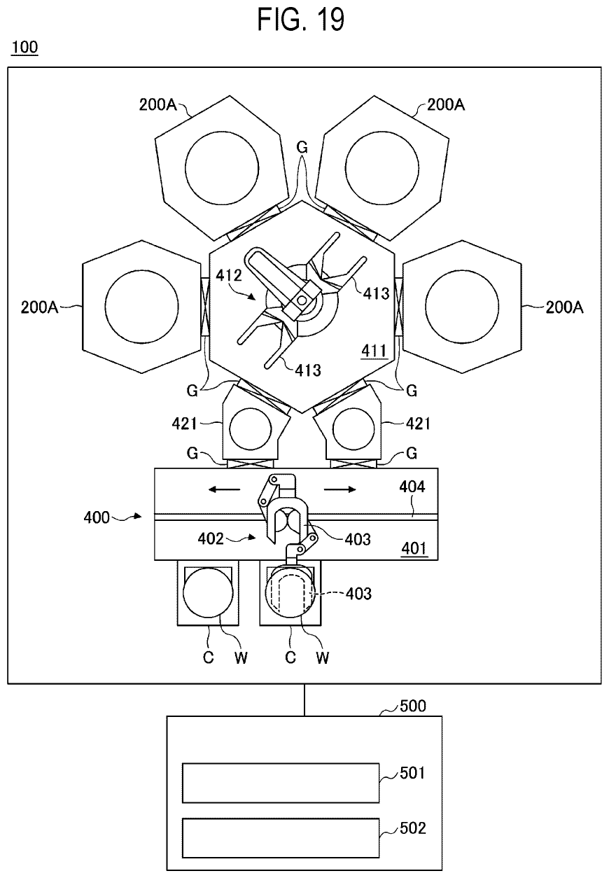

Next, a film forming apparatus 100 that performs the above-described film forming method will be described with reference to FIG. 19. As illustrated in FIG. 19, the film forming apparatus 100 includes a first processor 200A, a transporter 400, and a controller 500. The first processor 200A performs step S102 in FIG. 1. In addition, the film forming apparatus 100 may include a second processor configured to perform step S101B in FIG. 15. However, the first processor 200A may also perform both step S101B and step S102 in FIG. 15.

The transporter 400 transports the substrate W to the first processor 200A. The transporter 400 includes a first transport chamber 401 and a first transport mechanism 402. An internal atmosphere of the first transport chamber 401 is an atmospheric atmosphere. The first transport mechanism 402 is provided inside the first transport chamber 401. The first transport mechanism 402 includes an arm 403 configured to hold the substrate W, and travels along a rail 404. The rail 404 extends in an arrangement direction of a carrier C.

Further, the transporter 400 includes a second transport chamber 411 and a second transport mechanism 412. An internal atmosphere of the second transport chamber 411 is a vacuum atmosphere. The second transport mechanism 412 is provided inside the second transport chamber 411. The second transport mechanism 412 includes an arm 413 configured to hold the substrate W, and the arm 413 is arranged to be movable in vertical and horizontal directions and to be rotatable around a vertical axis. The first processor 200A is connected to the second transport chamber 411 via a gate valve G.

Furthermore, the transporter 400 includes a load lock chamber 421 between the first transport chamber 401 and the second transport chamber 411. An internal atmosphere of the load lock chamber 421 is switched between a vacuum atmosphere and an atmospheric atmosphere by a pressure regulating mechanism (not illustrated). Thereby, the interior of the second transport chamber 411 may always be maintained in a vacuum atmosphere. Further, introduction of a gas from the first transport chamber 401 to the second transport chamber 411 may be prevented. Gate valves G are provided between the first transport chamber 401 and the load lock chamber 421 and between the second transport chamber 411 and the load lock chamber 421.

The controller 500 is, for example, a computer and includes a computational part 501 such as a central processing unit (CPU) and a storage 502 such as a memory. The storage 502 stores a program that controls various types of processes executed in the film forming apparatus 100. The controller 500 causes the computational part 501 to execute the program stored in the storage 502, thereby controlling the operation of the film forming apparatus 100. The controller 500 controls the first processor 200A and the transporter 400 to perform the above-described film forming method.

Next, the operation of the film forming apparatus 100 will be described. First, the first transport mechanism 402 removes the substrate W from the carrier C, and transports the removed substrate W to the load lock chamber 421 to discharge the same from the load lock chamber 421. Subsequently, the internal atmosphere of the load lock chamber 421 is switched from the atmospheric atmosphere to the vacuum atmosphere. Thereafter, the second transport mechanism 412 removes the substrate W from the load lock chamber 421, and transports the removed substrate W to the first processor 200A.

Next, the first processor 200A performs step S102 in FIG. 1. Thereafter, the second transport mechanism 412 removes the substrate W from the first processor 200A, and transports the removed substrate W to the load lock chamber 421 to discharge the same from the load lock chamber 421. Subsequently, the internal atmosphere of the load lock chamber 421 is switched from the vacuum atmosphere to the atmospheric atmosphere. Thereafter, the first transport mechanism 402 removes the substrate W from the load lock chamber 421, and accommodates the removed substrate W in the carrier C. Then, processing of the substrate is terminated.

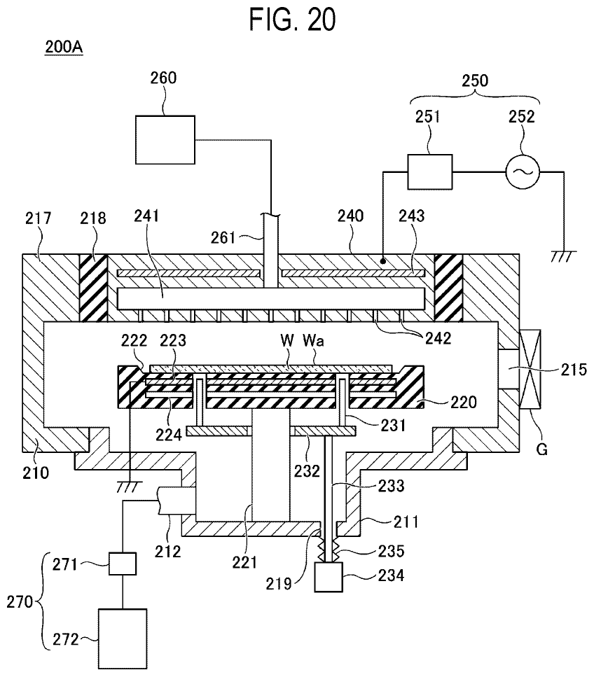

Next, the first processor 200A will be described with reference to FIG. 20. The first processor 200A includes a substantially cylindrical airtight processing container 210. An exhaust chamber 211 is provided on a bottom wall central portion of the processing container 210. The exhaust chamber 211 has, for example, a substantially cylindrical shape that protrudes downward. An exhaust pipe 212 is connected to the exhaust chamber 211, for example, on the side surface of the exhaust chamber 211.

An exhaust source 272 is connected to the exhaust pipe 212 via a pressure controller 271. The pressure controller 271 includes, for example, a pressure regulating valve such as a butterfly valve. The exhaust pipe 212 is configured to decompress the interior of the processing container 210 by using the exhaust source 272. The pressure controller 271 and the exhaust source 272 constitute a gas discharge mechanism 270 configured to discharge gases inside the processing container 210.

A transport port 215 is provided on the side surface of the processing container 210. The transport port 215 is opened or closed by the gate valve G. The loading and unloading of the substrate W between the inside of the processing container 210 and the second transport chamber 411 (see FIG. 19) are achieved through the transport port 215.

A stage 220, which serves as a holder configured to hold the substrate W, is provided within the processing container 210. The stage 220 holds the substrate W horizontally with the substrate surface Wa facing upward. The stage 220 is formed in a substantially circular shape in a plan view, and is supported by a support member 221. On the surface of the stage 220, a substantially circular recess 222 configured to place the substrate W having a diameter of 300 mm, for example is formed. The recess 222 has an inner diameter slightly larger than the diameter of the substrate W. The recess 222 is configured, for example, to have a depth which is substantially the same as the thickness of the substrate W. The stage 220 is made of a ceramic material such as aluminum nitride (AlN), for example. Further, the stage 220 may be made of a metallic material such as nickel (Ni). In addition, instead of the recess 222, a guide ring configured to guide the substrate W may be provided on a surface periphery of the stage 220.

For example, a grounded lower electrode 223 is embedded in the stage 220. A heating mechanism 224 is embedded below the lower electrode 223. The heating mechanism 224 heats the substrate W placed on the stage 220 to a set temperature upon being supplied with power supplied from a power supply (not illustrated) based on a control signal from the controller 500 (see FIG. 19). In a case where the entire stage 220 is made of a metal, since the entire stage 220 functions as a lower electrode, the lower electrode 223 may not be embedded in the stage 220. The stage 220 is provided with a plurality of (for example, three) lifting pins 231 configured to hold and vertically move the substrate W placed on the stage 220. The material of the lifting pins 231 may be, for example, ceramics such as alumina (Al₂O₃) or quartz. Lower ends of the lifting pins 231 are attached to a support plate 232. The support plate 232 is connected to a lifting mechanism 234 provided outside the processing container 210 via a lifting shaft 233.

The lifting mechanism 234 is attached, for example, to the bottom of the exhaust chamber 211. A bellows 235 is provided between the lifting mechanism 234 and an opening 219 for the lifting shaft 233 formed in the lower surface of the exhaust chamber 211. The support plate 232 may be shaped to be vertically movable without interfering with the support member 221 of the stage 220. The lifting pins 231 are configured to be vertically movable between above the surface of the stage 220 and below the surface of the stage 220 by the lifting mechanism 234.

A gas supplier 240 is provided on a ceiling wall 217 of the processing container 210 via an insulating member 218. The gas supplier 240 forms an upper electrode and is opposite to the lower electrode 223. A radio frequency power supply 252 is connected to the gas supplier 240 via a matcher 251. The radio frequency power supply 252 supplies radio frequency power in the range of 100 kHz to 2.45 GHz, specifically in the range of 450 kHz to 100 MHz to the upper electrode (gas supplier 240). Thereby, a radio frequency electric field is generated between the upper electrode (gas supplier 240) and the lower electrode 223, resulting in the generation of a capacitively coupled plasma. A plasma generator 250 configured to generate a plasma includes the matcher 251 and the radio frequency power supply 252. In addition, the plasma generator 250 is not limited to generating the capacitively coupled plasma, but may also generate other types of plasma such as inductively coupled plasma or remote plasma. In addition, it is unnecessary for the gas supplier 240 to form the upper electrode and the lower electrode 223 is also not required in steps that do not generate a plasma.

The gas supplier 240 includes a hollow gas supply chamber 241. A large number of holes 242 configured to disperse and supply a processing gas into the processing container 210 are evenly arranged, for example, on the lower surface of the gas supply chamber 241. A heating mechanism 243 is embedded, for example, above the gas supply chamber 241 in the gas supplier 240. The heating mechanism 243 is heated to a set temperature upon being supplied with power from a power supply (not illustrated) based on a control signal from the controller 500.

A gas supply mechanism 260 is connected to the gas supply chamber 241 through a gas supply path 261. The gas supply mechanism 260 supplies the gases used in steps in FIG. 1 or 15 to the gas supply chamber 241 through the gas supply path 261. The gas supply mechanism 260 includes, although not illustrated, an individual pipe for each type of gas, an on-off valve provided in the middle of the individual pipe, and a flow rate controller provided in the middle of the individual pipe. When the on-off valve opens the individual pipe, a gas is supplied from a supply source to the gas supply path 261. A supply amount of the gas is controlled by the flow rate controller. On the other hand, when the on-off valve closes the individual pipe, the supply of the gas from the supply source to the gas supply path 261 is stopped.

### EXAMPLES

Next, examples will be described. Examples 1, 2, 4, 5 and 7 below are examples, and Examples 3, 6 and 8 below are comparative examples.

### Example 1

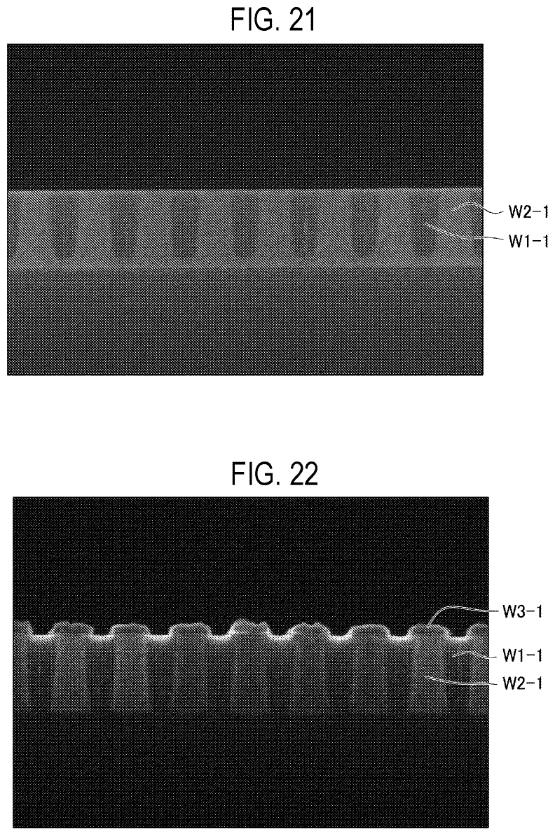

In Example 1, as illustrated in FIG. 21, a substrate having a BN film W1-1 and a SiO film W2-1 on the substrate surface was prepared, and step S102 illustrated in FIG. 1 was performed under a processing condition illustrated in Table 1. In Example 1, the first film was the BN film W1-1, the second film was the SiO film W2-1, the raw material gas was a TiCl₄ gas, the reactant gas was a NH₃ gas, the replacement gas was an O₂ gas, and the third film was a TiON film W3-1.

TABLE 1

| | | | | | | Number |
|---|---|---|---|---|---|---|
| | | Time | Supplied | | Temperature | of |
| | Step | [sec] | gas | RF | [° C.] | executions |
| Exam- | S102a | 2 | TiCl₄ + Ar | OFF | 350 | 300 |
| ple 1 | S102b | 5 | Ar | OFF | | |
| | S102h | 2 | NH₃ + Ar | OFF | | |
| | S102c | 2 | NH₃ + Ar | ON | | |
| | S102d | 5 | Ar | OFF | | |
| | S102i | 1 | O₂ + Ar | OFF | | |
| | S102f | 2 | O₂ + Ar | ON | | |
| | S102j | 1 | Ar | OFF | | |

In Table 1, “ON” for “RF” indicates that the gas was plasma-excited by using radio frequency power. Further, “OFF” for “RF” indicates that plasma excitation of the gas was not performed. The same applies to Tables 2 and 3 below. As illustrated in Table 1, the gas was plasma-excited in steps S102c and S102f.

As illustrated in Table 1, step S102 was performed by sequentially repeating S102a, S102b, S102h, S102c, S102d, S102i, S102f, and S102j 300 times (L=1, M=300 illustrated in FIG. 2). The details of S102a, S102b, S102c, S102d and S102f, except for S102h, S102i, and S102j, are the same as already described. In this case, S102h is a step performed before S102c to stabilize the flow rate of the reactant gas used in S102c. Further, S102i is a step performed before S102f to stabilize the flow rate of the replacement gas used in S102f. S102j is a step that purges any excess replacement gas that was not adsorbed on the substrate surface in S102f.

In Example 1, the supplying the replacement gas (S102f) was performed while alternately repeating the supplying the raw material gas (S102a) and the supplying the reactant gas (S102c). As a result, as illustrated in FIG. 22, the TiON film W3-1 was selectively formed on the SiO film W2-1 with respect to the BN film W1-1. The TiON film W3-1 was hardly formed on the surface of the BN film W1-1.

### Example 2

In Example 2, a substrate processing was performed in the same manner as in Example 1, except that the replacement gas was supplied to the substrate surface in S102f without being plasma-excited. As a result, as illustrated in FIG. 23, a TiON film W3-2 was selectively formed on a SiO film W2-2 with respect to a BN film W1-2. The TiON film W3-2 was hardly formed on the surface of the BN film W1-2.

### Example 3

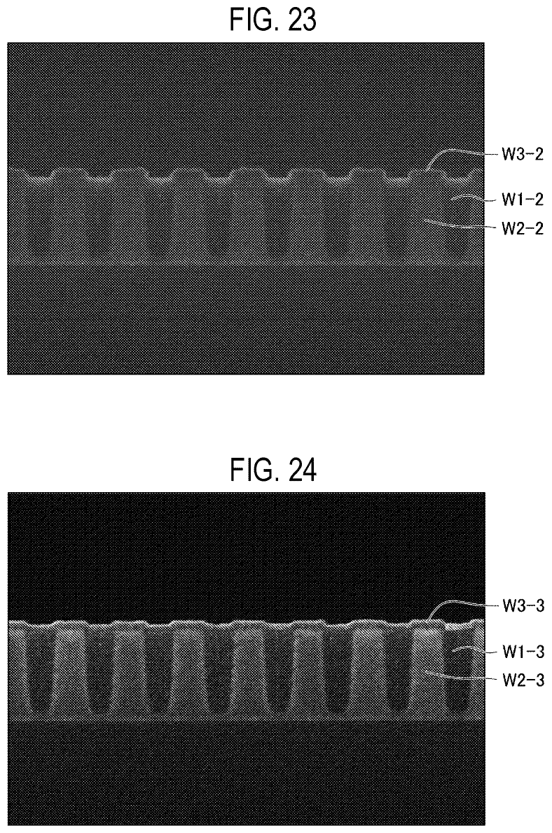

In Example 3, a substrate processing was performed in the same manner as in Example 1, except that S102i, S102f, and S102j were not performed (as a result, the formed third film was a TiN film, instead of a TiON film). As a result, as illustrated in FIG. 24, a BN film W1-3 inhibited formation of a TiN film W3-3, and a difference in the film thickness of the TiN film W3-3 was recognized between the surface of the BN film W1-3 and the surface of a SiO film W2-3. However, the TiN film W3-3 was formed on both the surfaces of the BN film W1-3 and the SiO film W2-3.

From the results of Examples 1 and 3, or the results of Examples 2 and 3, it can be seen that performing the supplying the replacement gas (S102f) while alternately repeating the supplying the raw material gas (S102a) and the supplying the reactant gas (S102c) is effective for maintaining the effect of the BN film inhibiting the formation of the TiON film W3.

### Example 4

In Example 4, a substrate processing was performed in the same manner as in Example 1, except that step S102 in FIG. 1 was performed under a processing condition illustrated in Table 2. In Example 4, the first film was a BN film W1-4, the second film was a SiO film W2-4, the raw material gas was a TiCl₄ gas, the reactant gas was a H₂ gas, the replacement gas was an O₂ gas, and the third film was a TiO film W3-4. As illustrated in Table 2, the gas was formed into the plasma in steps S102c and S102f.

TABLE 2

| | | | | | | Number |
|---|---|---|---|---|---|---|
| | | Time | Supplied | | Temperature | of |
| | Step | [sec] | gas | RF | [° C.] | executions |
| Exam- | S102a | 2 | TiCl₄ + Ar | OFF | 350 | 300 |
| ple 4 | S102b | 5 | Ar | OFF | | |
| | S102h | 2 | H₂ + Ar | OFF | | |
| | S102c | 2 | H₂ + Ar | ON | | |
| | S102d | 5 | Ar | OFF | | |
| | S102i | 1 | O₂ + Ar | OFF | | |
| | S102f | 2 | O₂ + Ar | ON | | |
| | S102j | 1 | Ar | OFF | | |

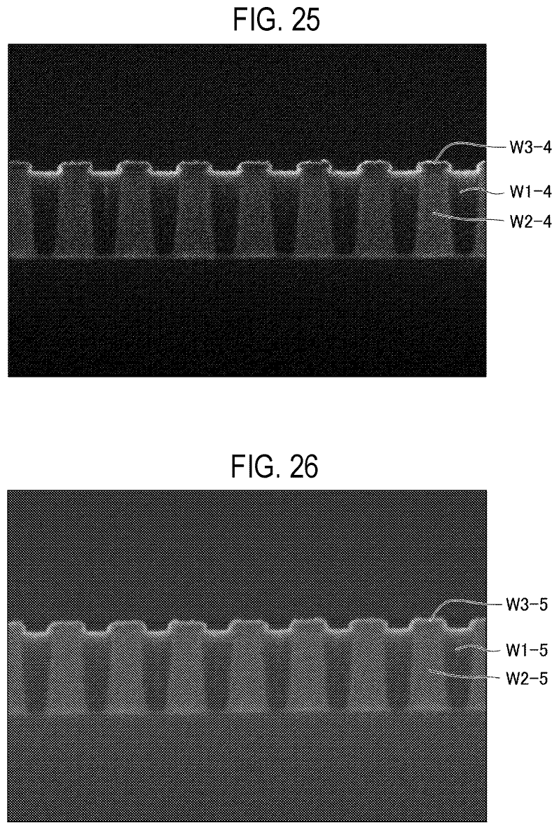

In Example 4, the replacement gas (S102f) was supplied while alternately repeating the supplying the raw material gas (S102a) and the supplying the reactant gas (S102c). As a result, as illustrated in FIG. 25, the TiO film W3-4 was selectively formed on the SiO film W2-4 with respect to the BN film W1-4. The TiO film W3-4 was hardly formed on the surface of the BN film W1-4.

### Example 5

In Example 5, a substrate processing was performed in the same manner as in Example 4, except that the replacement gas was supplied to the substrate surface in S102f without being formed into the plasma. As a result, as illustrated in FIG. 26, a TiO film W3-5 was selectively formed on a SiO film W2-5 with respect to a BN film W1-5. The TiO film W3-5 was hardly formed on the surface of the BN film W1-5.

### Example 6

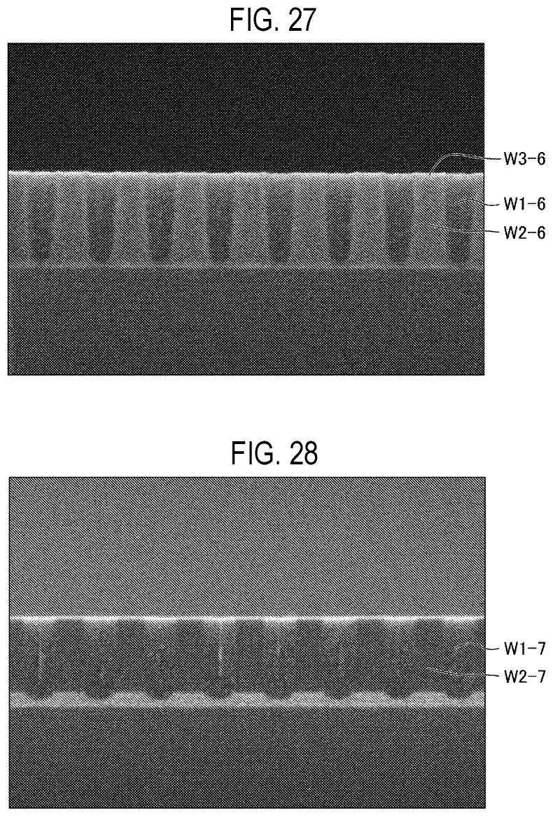

In Example 6, a substrate processing was performed in the same manner as in Example 4, except that S102i, S102f, and S102j were not performed (as a result, the formed third film was a Ti film, instead of a TiO film). As a result, as illustrated in FIG. 27, a Ti film W3-6 was formed on both the surfaces of a BN film W1-6 and a SiO film W2-6.

It can be seen from the results of Examples 4 and 6, or the results of Examples 5 and 6 that performing the supplying the replacement gas (S102f) while alternately repeating the supplying the raw material gas (S102a) and the supplying the reactant gas (S102c) is effective for maintaining the effect of the BN film inhibiting the formation of a Ti-containing film.

### Example 7

In Example 7, as illustrated in FIG. 28, a substrate having a BN film W1-7 and a Si film W2-7 on the substrate surface was prepared, and step S102 in FIG. 1 was performed under a processing condition illustrated in Table 3. In Example 7, the first film was the BN film W1-7, the second film was the Si film (specifically, an amorphous Si film) W2-7, the raw material gas was an Si₂Cl₆ gas, the reactant gas was a NH₃ gas, the replacement gas was an O₂ gas, and the third film was a SiON film W3-7. As illustrated in Table 3, the gas was formed into the plasma in steps S102c and S102f.

TABLE 3

| | | | | | | Number |
|---|---|---|---|---|---|---|
| | | Time | Supplied | | Temperature | of |
| | Step | [sec] | gas | RF | [° C.] | executions |
| Exam- | S102a | 2 | Si₂Cl₆ + Ar | OFF | 350 | 200 |
| ple 7 | S102b | 10 | Ar | OFF | | |
| | S102h | 2 | NH₃ + Ar | OFF | | |
| | S102c | 2 | NH₃ + Ar | ON | | |
| | S102d | 5 | Ar | OFF | | |
| | S102i | 1 | O₂ + Ar | OFF | | |
| | S102f | 2 | O₂ + Ar | ON | | |
| | S102j | 8 | Ar | OFF | | |

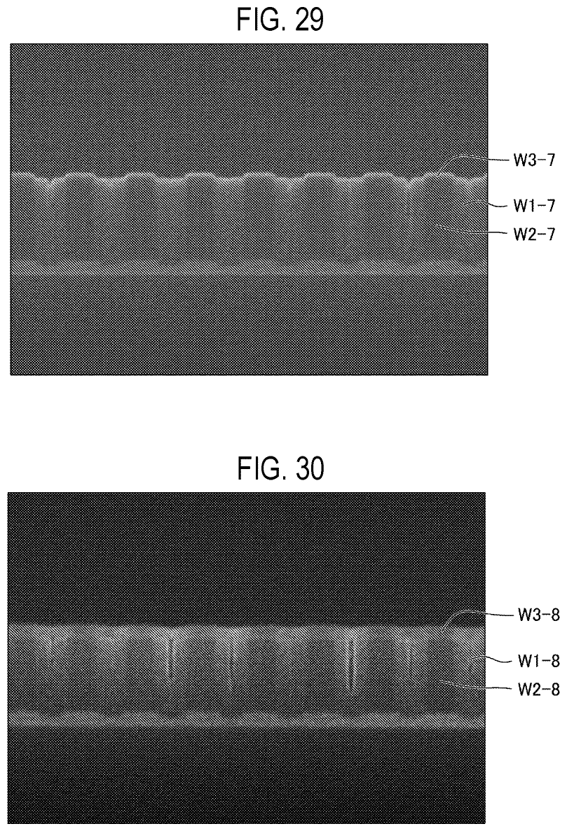

In Example 7, the supplying the replacement gas (S102f) was performed while alternately repeating the supplying the raw material gas (S102a) and the supplying the reactant gas (S102c). As a result, as illustrated in FIG. 29, the SiON film W3-7 was selectively formed on the Si film W2-7 with respect to the BN film W1-7. The SiON film W3-7 was hardly formed on the surface of the BN film W1-7.

### Example 8

In Example 8, a substrate processing was performed in the same manner as in Example 7, except that S102i, S102f, and S102j were not performed (as a result, the formed third film was a SiN film, instead of a SiON film). As a result, as illustrated in FIG. 30, a SiN film W3-8 was formed on both the surfaces of a BN film W1-8 and a Si film W2-8.

It can be seen from the results of Examples 7 and 8 that performing the supplying the replacement gas (S102f) while alternately repeating the supplying the raw material gas (S102a) and the supplying the reactant gas (S102c) is effective for maintaining the effect of the BN film inhibiting the formation of an Si-containing film.

According to an embodiment of the present disclosure, it is possible to selectively form a third film on a second film made of a material different from that of a first film containing boron with respect to the first film.

Although the embodiments of the film forming method and the film forming apparatus according to the present disclosure have been described above, the present disclosure is not limited thereto. Various changes, modifications, substitutions, additions, deletions, and combinations are possible within the scope set forth in the claims. These may well belong to the technical scope of the present disclosure.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method comprising:
preparing a substrate including a first film containing boron and a second film made of a material different from that of the first film on different regions of a surface of the substrate; and
forming a third film selectively on the second film with respect to the first film,
wherein the forming the third film includes supplying a raw material gas containing halogen and an element X other than halogen to the surface of the substrate and supplying a reactant gas that reacts with an adsorbate of the raw material gas to the surface of the substrate, thus forming the third film containing the element X, and includes supplying a replacement gas to replace an adsorbate of the reactant gas on a surface of the first film during repetition of alternately or simultaneously performing the supplying the raw material gas and the supplying the reactant gas, so as to prevent adsorption of the raw material gas on the surface of the first film.

2. The film forming method of claim 1, wherein the preparing the substrate includes selectively forming the first film on a fourth film made of a material different from that of the second film with respect to the second film.

3. The film forming method of claim 2, further comprising
after the forming the third film, selectively reforming the first film on the first film or on the fourth film with respect to the third film; and
with respect to the reforming the first film, selectively forming the third film again on the third film.

4. The film forming method of claim 1, wherein the reactant gas is a gas containing nitrogen.

5. The film forming method of claim 1, wherein the reactant gas is a gas containing hydrogen.

6. The film forming method of claim 1, wherein the reactant gas is a gas containing oxygen.

7. The film forming method of claim 1, wherein the replacement gas is a gas containing halogen.

8. The film forming method of claim 1, wherein the replacement gas is a gas containing oxygen.

9. The film forming method of claim 1, wherein the replacement gas is a gas containing nitrogen.

10. The film forming method of claim 1, wherein the second film substantially does not contain boron.

11. The film forming method of claim 1, wherein before the forming the third film, the substrate has a recess on the surface including the first film and the second film, and the first film is only exposed inside the recess and is exposed at least on a bottom surface of the recess.

12. The film forming method of claim 1, wherein before the forming the third film, the substrate has a recess on the surface including the first film and the second film, and the second film is only exposed inside the recess and is exposed at least on a bottom surface of the recess.

13. The film forming method of claim 1, wherein the element X includes a metal element.

14. The film forming method of claim 1, wherein the element X includes a transition metal element.

15. The film forming method of claim 1, wherein the element X includes a semiconductor element.

16. The film forming method of claim 1, wherein the forming the third film includes alternately supplying the raw material gas and the reactant gas, and includes supplying the reactant gas in a plasma state.

17. The film forming method of claim 1, wherein the forming the third film includes performing a process, one or more times, the process including sequentially performing:
supplying the raw material gas containing an element X1 as the element X;
supplying the raw material gas containing an element X2, which is different from the element X1, as the element X; and
supplying the reactant gas.

18. The film forming method of claim 1, wherein the forming the third film includes:
performing a process, one or more times, the process including sequentially performing:
supplying the raw material gas containing an element X1 as the element X; and
supplying the reactant gas; and
performing a process, one or more times, the process including sequentially performing:
supplying the raw material gas containing an element X2, which is different from the element X1, as the element X; and
supplying the reactant gas.

19. A film forming apparatus comprising:
a processing container configured to accommodate a substrate;
a holder configured to hold the substrate inside the processing container,
a supplier configured to supply a gas to a surface of the substrate held by the holder, and
a controller configured to control the supplier,
wherein the controller performs a control to perform the film forming method of claim 1.
